(19) United States
(12) Patent Application Publication
(10) Pub. No.: US 2007/0111468 A1
(43) Pub. Date: May 17, 2007

(54) METHOD FOR FABRICATING DISLOCATION-FREE STRESSED THIN FILMS

(75) Inventors: Ya-Hong Xie, Beverly Hills, CA (US); Jeehwan Kim, Los Angeles, CA (US)

Correspondence Address: Vista IP Law Group LLP, 2040 MAIN STREET, 9TH FLOOR, IRVINE, CA, 92614, US

(73) Assignee: The Regents of the University of California, Oakland, CA (US)

(21) Appl. No.: 11/458,641

(22) Filed: Jul. 19, 2006

Related U.S. Application Data
(60) Provisional application No. 60/700,448, filed on Jul. 19, 2005.

(51) Int. Cl. H01L 21/76

(52) U.S. Cl. 438/424

(57) ABSTRACT

A method of forming a stressed thin film on a substrate includes the steps of depositing a thin film of silicon on a first substrate and transforming the first substrate into a porous substrate. The porous substrate containing the thin film of silicon is then transformed into a stressed state such that at least a portion of the stress is transferred to the thin film. The thin film may be under compressive stress or tensile stress. For example, volumetric expansion of the porous substrate imparts tensile stress to the thin film while volumetric contraction of the porous substrate imparts compressive stress to the thin film. The porous substrate containing the stressed thin film of silicon is then bonded to a second substrate. The porous substrate is removed so as to deposit the stressed thin film of silicon to the second substrate.

### REFERENCE TO RELATED APPLICATIONS

This Application claims priority to U.S. Provisional Patent Application No. 60/700,448 filed on Jul. 19, 2005. U.S. Provisional Patent Application No. 60/700,448 is incorporated by reference as if set forth fully herein.

### STATEMENT REGARDING FEDERALLY SPONSORED RESEARCH AND DEVELOPMENT

The U.S. Government may have a paid-up license in this invention and the right in limited circumstances to require the patent owner to license others on reasonable terms as provided for by the terms of contract number: No. FA9550-04-1-0370 awarded by the United States Air Force.

### FIELD OF THE INVENTION

The field of the invention generally relates to methods for forming stressed (e.g., compressive of tensile) thin films. More particularly, the field of the invention relates to methods used to form dislocation-free stressed thin films.

### BACKGROUND OF THE INVENTION

The use of strained silicon devices is known to increase semiconductor device performance. For example, in the context of transistors, strained silicon increases the transistor drive current which improves switching speed by making current flow more smoothly. Generally, a very thin layer of single-crystal silicon with built in stress (or strain) improves drive current making the devices run faster. When the layer of silicon is under stress, the silicon lattice lets electrons and holes flow with less resistance. For transistors, the lower resistance translates in to faster switching properties, thereby permitting semiconductor devices to operate at faster speeds.

Because of the advantages inherent in the strained lattice structure, strained silicon or silicon germanium based devices have become an attractive alternative to current microelectronic devices that are composed of a silicon channel layer on a silicon substrate. Several approaches have been developed to form strained silicon on substrates. For example, relaxed silicon germanium buffer layers have been employed as a “virtual substrate” to grow strained silicon. Typically, the relaxed silicon germanium buffer layer, which has a higher lattice constant than the silicon substrate, is formed in a graded manner and is used as an epitaxial growth template.

If a constant (i.e., non-graded composition) silicon germanium buffer layer is used, high densities of dislocations nucleate during growth and interact with one another. This interaction prevents dislocations from propagating to the edge of the substrate (e.g., a wafer), thereby leaving a significant number of threading arms on the surface of the silicon germanium layer. In contrast, by grading the germanium composition during growth of the relaxed silicon germanium layer on a silicon substrate, the nucleation rate of dislocations is retarded by reducing the strain accumulation rate. Consequently, the interaction between dislocations is reduced, significantly reducing the density of threading arm dislocations on the surface of the silicon germanium layer. For example, the threading dislocation density in a constant (non-graded) silicon germanium grown directly on a silicon substrate is on the order of about 10^{8˜9}/cm². If a graded silicon germanium buffer layer is formed on a silicon substrate, the threading dislocation density improves to around 10^{4˜5}/cm².

Unfortunately, there are several disadvantages to graded silicon germanium buffer layers. First, the threading dislocation density, while lower in graded buffer layers, is still non-zero, which leads to degradation of electron and hole mobility. Moreover, a large thickness of graded silicon germanium buffer layer is needed for achieving low threading dislocation densities. The large thickness increases the size of the devices as well as the cost of production. Second, the strain-relaxed graded silicon germanium buffer layer has a rough surface which degrades the mobility of strained silicon. In addition, the strain at the top layer of silicon is not homogeneous due to the stress fields from buried dislocations, which also adversely affects carrier transport.

Another problem with existing techniques is that the stressed thin films have lattice constants at discrete values due to the availability of limited types of substrates along the spectrum of potential lattice constant values. It would be beneficial if the lattice constant could be varied or modified, to some extent, to expand the coverage of total available spectrum of lattice constants. In this regard, by expanding the universe of potential lattice constants would enable the creation of microelectronic devices within unique and advantageous properties.

### SUMMARY OF THE INVENTION

In a first aspect of the invention, a method of forming a stressed thin film on a substrate includes the steps of depositing a thin crystalline film of silicon on a first substrate, and subsequently transforming the first substrate into a porous substrate via an electrochemical process. The porous substrate containing the thin film of silicon is then transformed into a stressed state such that at least a portion of the stress is transferred to the thin film. The thin film may be under compressive stress or tensile stress. For example, volumetric expansion of the porous substrate imparts tensile stress to the thin film while volumetric contraction of the porous substrate imparts compressive stress to the thin film. The porous substrate containing the stressed thin film of silicon is then bonded to a second substrate. The porous substrate is removed so as to deposit the stressed thin film of silicon to the second substrate.

In another aspect of the invention, a method of forming a stressed semiconductor thin film on a substrate includes the steps of providing a porous substrate that includes an oxide layer disposed thereon. The porous substrate is then bonded to a transfer substrate formed from a semiconducting material. A portion of the transfer substrate is removed so as to leave a semiconductor thin film on the porous substrate. The porous substrate containing the semiconductor thin film is transformed so as to form a stressed semiconductor thin film. The porous substrate containing the stressed semiconductor thin film is bonded to a recipient substrate. The porous substrate is then removed along with the oxide layer to expose the stressed semiconductor thin film on the recipient substrate.

In still another aspect of the invention, an article of manufacture includes a substrate, an intermediate layer disposed on the substrate, and a stressed thin film overlying the intermediate layer. The stressed thin film is formed from a semiconductor material and is homogeneously stressed across substantially the entire surface of the substrate. The stressed thin film is formed on a first, separate substrate that is subsequently transferred to a second, final substrate.

### BRIEF DESCRIPTION OF THE DRAWINGS

FIG. 1A illustrates a process of forming a stressed thin film on a substrate according to one embodiment of the invention.

FIG. 2 illustrates an anodization cell for forming a porous substrate.

FIG. 3 illustrates an oxidation chamber that is used to form the stressed thin film layer according to one embodiment of the invention.

FIGS. 4A and 4B illustrate a process of forming a stressed semiconductor thin film on a substrate according to another embodiment of the invention.

### DETAILED DESCRIPTION OF THE PREFERRED EMBODIMENTS

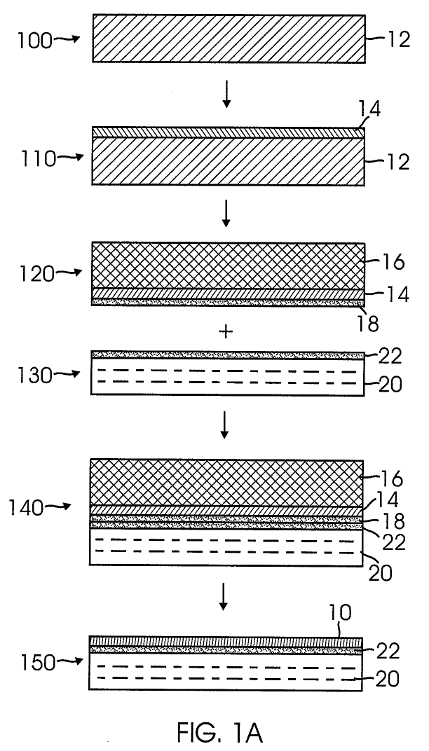

FIG. 1A illustrates a process of forming a homogeneously stressed thin film 10 on a transfer substrate 20 according to one embodiment of the invention. Initially, in step 100, a first substrate 12 is provided. The first substrate 12 may be formed from a semiconductor material, or in some instances, an insulator material. For example, in one aspect of the embodiment, the substrate 12 is formed from a doped, p+ type silicon substrate. The substrate 12 may be formed as wafer or the like such that the homogeneously stressed thin film 10 (described in more detail below) may be formed across (and subsequently transferred from) substantially the entire surface of the substrate 12. The p+ silicon substrate 12 is heavily doped with a doping agent such as boron, although other doping agents known to those skilled in the art may also be used.

In step 110, an un-doped epilayer 14 of silicon is formed on the doped, p+ type silicon substrate 12. Alternatively, n-type silicon may be used for the epilayer 14. The epilayer 14 may be grown or deposited using a chemical vapor deposition (CVD) process or other epitaxial growth process. The thickness of the epilayer 14 may vary but generally is below around 100 nm. The thickness of the epilayer 14 should fall below the critical thickness at which dislocations are generated. The critical thickness may vary as a function of temperature and strain. Generally, the operating range for the thickness of the epilayer 14 should fall below the thickness/strain curve of so-called metastable silicon at any given temperature. In other words, the critical thickness is the thickness of the epilayer 14 at which the homogeneous strain energy becomes so large that misfit dislocations are introduced. The calculated critical layer thickness of latticed mismatched stressed heterostructures may be obtained using the methods illustrated in R. People at al., Calculation of Critical Layer Thickness Versus Lattice Mismatch For GeₓSi₁₋ₓ/Si Strained-Layer Heterostructures, Applied Physics Letters, Vol. 47, p. 322-24 (1985).

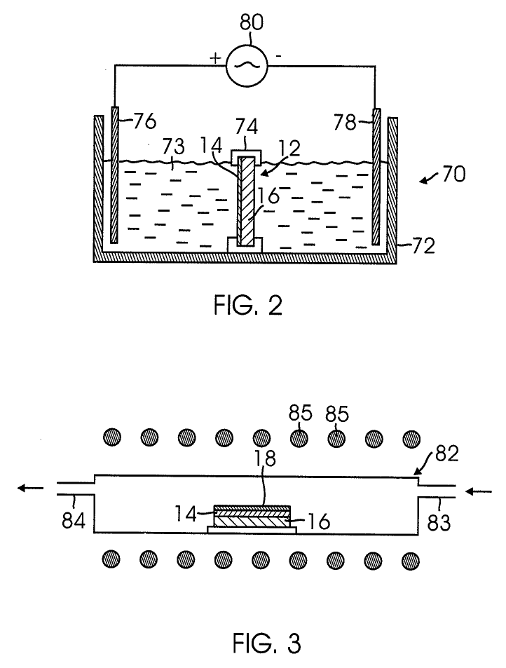

Next, as illustrated in step 120, the doped, p+ silicon substrate 12 is transformed into porous silicon 16. This process may be carried out by placing the p+ silicon substrate 12 with the epilayer 14 into an anodization cell 70 of the type disclosed in FIG. 2. The anodization cell 70 includes a housing or cell 72 that holds an electrolyte 73. For example, the housing 72 may be formed from an inert material such as PTFE. The anodization cell 70 includes a substrate holder 74 which may take the form of a wafer chuck or the like to hold the substrate 12 within the solution of electrolyte 74. The anodization cell 70 includes an anode 76 and a cathode 78 that are immersed on opposing sides of the substrate 12. The anode 76 is positioned on the side of the cell 70 in contact with the epilayer 14 while the cathode 78 is positioned on the side of the cell 70 in contact with the substrate 12. The cathode 78 may be covered with a platinum film to assist in the anodization process. The anode 76 and cathode 78 are connected to a current source 80 that drives the anodization cell 70. The anodization cell 70 is operated by applying a constant current via the current source 80.

The anodization process taking place within the anodization cell 70 transforms the doped, p+ silicon substrate 12 into porous silicon 16. Anodization of the doped, p+ silicon substrate 12 is stopped when the advancing anodization front reaches the interface with the epilayer 14. During the anodization process at constant applied current, the measured voltage drop as a function of time stabilizes once the advancing anodization front reaches the interface substrate 12 and the epilayer 14. At this point, the anodization process is stopped and the porous silicon substrate 16 is removed from anodization cell 70.

In one aspect of the invention, the porous silicon 16 has a substantially uniform distribution of pores throughout the entire thickness of the porous silicon 16. That is to say, the pore size and pore distribution are substantially uniform across the entirety of the porous silicon 16. This feature of the invention permits subsequent uniform stressing of the porous silicon 16 (through volumetric expansion or contraction). The uniform stressing of the porous silicon 16 can then be transferred to the stressed thin film 10, thereby creating a homogeneously stressed thin film 10.

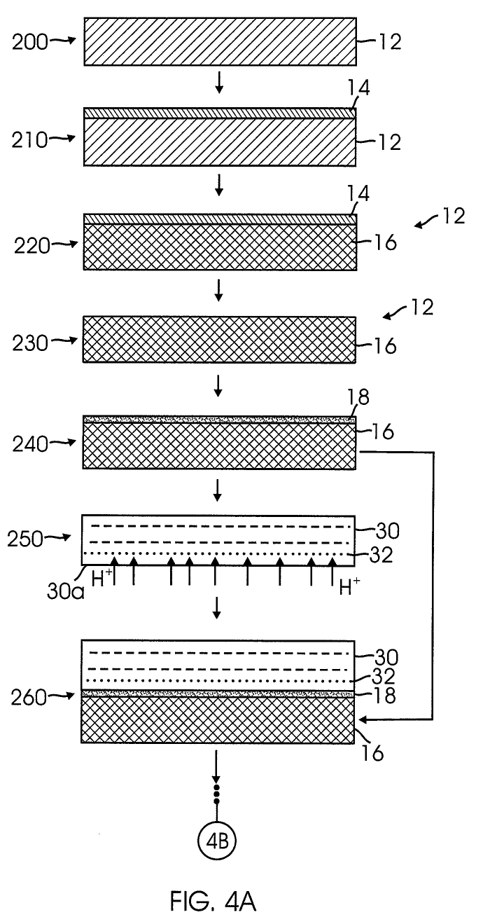

Next, and with reference to step 120 in FIG. 1A, the porous substrate 16 (with epilayer 14) is then dried and subject to an annealing process. The annealing process imparts a stress (e.g., tensile stress) to the epilayer 14. For example, in one aspect of this embodiment, the porous substrate 16 with epilayer 14 is subject to an oxidating environment. FIG. 3 illustrates a reaction chamber 82 used for the annealing process. The reaction chamber 82 includes an inlet 83 and outlet 84 and one or more heating elements 85 that are used to elevate the temperature of the reaction chamber 82. The porous substrate 16 with epilayer 14 is placed within the reaction chamber 82. Steam enriched with oxygen (O₂) is then passed into the reaction chamber 82 via the inlet 83. For example, O₂ flowing through boiling deionized (DI) water is used to create the heated steam. Oxidation of the porous substrate 16 may take place at a temperature range from about 200° C. to about 800° C. In one particular embodiment, the anodized samples are oxidized at around 500° C. in steam ambient at around 1 atm. Generally, the lower the temperature, the higher strain that can be achieved without dislocations being formed. Counterbalancing this is that lower temperatures increases process time because the oxidation rate is reduced.

In the annealing process taking place in the reaction chamber 82, the input steam decomposes to 2 H⁺+O⁻² and the oxygen reacts with the silicon surface of the pore walls to form SiO₂ (thereby consuming silicon). In other words, the silicon is replaced by SiO₂. The oxidation forms an oxide layer 18 (e.g., SiO₂) on the epilayer 14 in addition to the interior porous structure of the porous silicon substrate 16. This causes the porous silicon substrate 16 to undergo volumetric expansion. The expansion of the porous silicon substrate 16 imparts a tensile stress on the silicon epilayer 14. It should also be noted that the silicon epilayer 14 has a uniform thickness and a smooth interface is formed between the porous substrate 16 and the crystalline portion.

With reference to step 130, a second or transfer substrate 20 is provided. The transfer substrate 20 may be formed, for example, from silicon. With reference to FIG. 1A, the transfer substrate 20 includes an interface layer 22 (e.g., intermediate layer) disposed on at least one surface thereof. The interface layer 22 may be formed from the same or similar material as the oxidation layer 18 located on the epilayer 14. For example, the interface layer 22 may be formed from silicon dioxide (SiO₂). As seen in step 120, the substrate 12 containing the porous silicon 16, epilayer 14, and oxidation layer 18 is flipped or turned over such that the oxidation layer 18 is in a facing arrangement with the interface layer 22 of the transfer substrate 20. The transfer substrate 20 is then bonded to the substrate 12 containing the porous silicon 16 and epilayer 14 as is shown in step 140. The transfer substrate 20 may be bonded to the first substrate 12 via a hydrophilic wafer bonding process. A hydrophilic wafer bonding process generally involves cleaning the opposing contact surfaces of the respective substrates 12, 20 and annealing the touching substrates 12, 20 at an elevated temperature. One exemplary hydrophilic wafer bonding process that may be used in accordance with the invention is a low-temperature hydrophilic wafer bonding process of the type disclosed in Esser, Improved Low-Temperature Si-Si Hydrophilic Wafer Bonding, Journal of Electrochemical Society, 150 (30 G228-G231 (2003), which is incorporated by reference as if set forth fully herein.

Still referring to FIG. 1A, as shown in step 150, the bonded structure formed by the combined substrates 12, 20 is then subject to an etching process to remove the porous silicon 16. For example, the porous silicon 16 may be etched away by a solution of potassium hydroxide (KOH) and hydrogen fluoride (HF). The potassium hydroxide is used to etch away the porous silicon 16 while the hydrogen fluoride removes oxide (e.g., SiO₂) formed on the surface thereof. Of course, other etchants known to remove porous silicon 16 and oxides may also be used. During the etching process, a small layer or thickness of the now-formed stressed thin film 10 may be etched or removed but does affect the properties of the stressed thin film 10. Optionally, the now exposed stressed thin film 10 may be subject to additional CMP processing.

As an alternative to the embodiment described above, the oxide layer 18 is replaced with silicon nitride (Si₃N₄). Specifically, after the transformation of the doped, p+ silicon substrate 12 into porous silicon 16 by anodization, silicon nitride is deposited thereon. The silicon nitride may be deposited using low pressure chemical vapor deposition (LPCVD) which typically occurs at or around 800° C. although other temperatures used to deposit silicon nitride via LPCVD may also be used. Alternatively, silicon nitride may be deposited using plasma enhance chemical vapor deposition (PECVD). Typical temperatures associated with PECVD deposition of silicon nitride fall between around 100° C. to around 400° C. although other temperatures capable of silicon nitride deposition via PECVD are also contemplated. Silicon nitride deposition takes place outside an oxidative environment, for example, either in vacuum or in the presence of an inert gas. A layer of silicon nitride thus replaces the oxide layer 18 shown in step 120. The silicon nitride also enters the interstitial pores of the porous silicon 16. The deposition of silicon nitride within the porous silicon 16 causes contraction or shrinkage of the porous silicon 16 substrate 12. This, in turn, imparts a compressive stress on the silicon epilayer 14.

In this embodiment, after the bonding step (step 150), the porous silicon 16 is etched away using an etching solution. For example, the porous silicon 16 may be etched away by a solution of potassium hydroxide (KOH) and phosphoric acid (H₂PO₄). The potassium hydroxide is used to etch away the porous silicon 16 while the phosphoric acid removes silicon nitride formed on the surface thereof. Of course, other etchants may also be used to remove the porous silicon 16 and adherent silicon nitride layer.

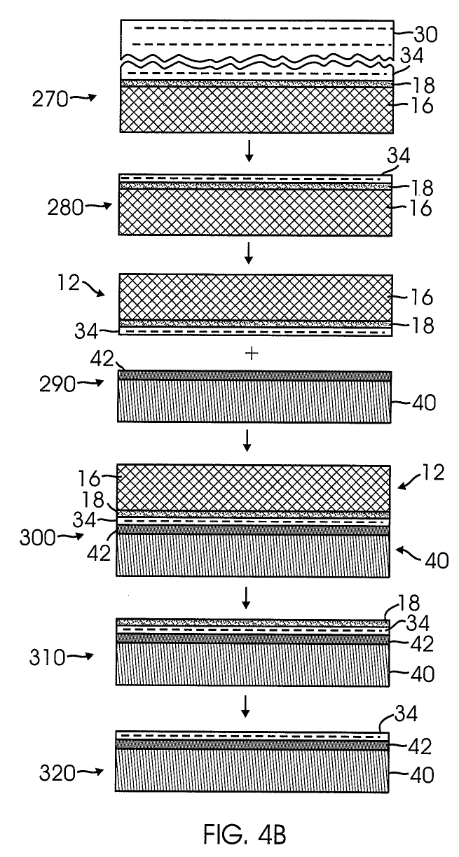

FIGS. 4A and 4B illustrate an alternative embodiment of the invention. With reference to FIG. 4A, a substrate 12 is provided as shown in step 200. The substrate 12 may be formed from a semiconductor material, or in some instances, an insulator material. For example, in one aspect of the embodiment, the substrate 12 is formed from a doped, p+ type silicon substrate. The substrate 12 may be formed as wafer or the like. A thin film or epilayer 14 of silicon is then grown on the substrate 12 as is shown in step 210. The epilayer 14 may be grown or deposited using a chemical vapor deposition (CVD) process or other epitaxial growth process. The substrate 12 with the epilayer 14 are then transferred to an anodization cell 70 such as the one illustrated in FIG. 2 to convert the doped, p+ type silicon substrate to porous silicon 16 (step 220) in the manner described herein.

Next, as illustrated in step 230, the thin film or epilayer 14 of silicon is removed. The thin film 14 may be removed using conventional CMP processing. The purpose of the thin film 14 in this embodiment is needed to form a substantially smooth or flat surface for subsequent processing steps. In an alternative embodiment, the formation of the thin film 14 may be bypassed entirely and CMP processing may be used to obtain the substantially smooth or flat surface. In step 240, the porous silicon 16 is then deposited with an oxide layer 18. Alternatively, the oxide layer 18 may be substituted with silicon nitride. For example, the oxide (or silicon nitride) layer 18 may be deposited using plasma enhanced chemical vapor deposition (PECVD). Still referring to step 240, the layer 18 may then be planarized by CMP processing to form a substantially flat upper surface. The flat surface facilitates subsequent wafer bonding of the porous silicon 16 with layer 18 to a transfer substrate (described in more detail below).

Referring now to FIG. 250, a transfer substrate 30 is provided. The transfer substrate 30 may be formed from a semiconductor material. For example, the transfer substrate 30 may include group IV elements such as silicon or germanium. Alternatively, the transfer substrate 30 may be formed from group III-V compounds such as, for example, indium phosphide (InP), gallium phosphide (GaP), indium antimonide (InSb), indium arsenide (InAs), gallium antimonide (GaSb), gallium nitride (GaN), and silicon carbide (SiC). In yet another alternative, the transfer substrate 20 may be formed from group II-VI compounds such as, for instance, zinc oxide (ZnO), zinc selenide (ZnSe), cadmium sulfide (CdS), and cadmium telluride (CdTe). In yet another alternative, the transfer substrate 20 may be formed from crystal materials having useful optical properties such as, for example, yttrium orthovanadate (YVO₄), titanium dioxide (TiO₂), calcium carbonate (CaCO₃), lithium niobate (LiNbO₃), and lithium tantalate (LiTaO₃). The transfer substrate 20 may also be formed from other crystalline structures such as sapphire, quartz, and other oxide layers having ferromagnetic or ferroelectric properties (e.g., SrTiO₃).

The transfer substrate 30 is then subject to hydrogen ion implantation. As seen in FIG. 4A, a front side 30a of the transfer substrate 30 is subject to hydrogen ion implantation to facilitate subsequent silicon film exfoliation (described below). The depth of penetration of the hydrogen ions in the front side 30a of the transfer substrate 30 is illustrated by the dotted line 32. Hydrogen ion implantation techniques are well known to those skilled in the art. For example, hydrogen ion implantation techniques used in connection with the so-called SMART-CUT process described in U.S. Pat. Nos. 5,374,564 and 5,993,677 and in B. Ghyselen et al., Engineering Strained Silicon on Insulator Wafers with the SMART CUT Technology, Solid-State Electronics 48, pp. 1285-1296 (2004) may be employed. The contents of the above-identified patents are incorporated by reference as if set fully herein.

Next, in step 260, the porous silicon 16 containing the oxide layer 18 is then bonded to the transfer substrate 30 via the front face 30a of the transfer substrate 30. The porous silicon-containing substrate 12 may be bonded to the transfer substrate 30 using a hydrophilic wafer bonding process like the those described herein. The porous silicon-containing substrate 12 and transfer substrate 30 may be subject to a low temperature anneal to establish the initial bonding. After initial bonding, the substrates 12, 30 are subject to a medium temperature annealing process used in the well known SMART-CUT process to thereby separate the transfer substrate 30 along the weakened region containing the implanted hydrogen ions. The separation of the transfer substrate 30 along the weakened region is illustrated in step 270 of FIG. 4B. The SMART-CUT process leaves an exfoliation layer 34 (i.e., a portion or layer of transfer substrate 30) bound to the porous silicon 16 via the layer 18 formed from either oxide or nitride.

Because the separation of the transfer substrate 30 along the weakened zone creates a rough surface, the porous silicon substrate 12 containing the oxide layer 18 and portion of the silicon transfer substrate 30 is then subject to a planarization step as is shown in step 280. For example, CMP processing may be used to form a substantially flat surface silicon exfoliation layer 34 from the transfer substrate 30.

Referring to step 290, the now polished substrate 12 containing the porous silicon 16, layer 18, and silicon exfoliation layer 34 is then subject to an annealing process. The annealing process imparts a stress (e.g., tensile) to the exfoliation layer 34. For example, the porous silicon substrate 12 with the oxide layer 18 and silicon exfoliation layer 34 is then subject to an oxidating environment. For example, the structure shown in step 280 may be placed in a reaction chamber 82 of the type disclosed in FIG. 3. Oxidation of the porous silicon 16 causes the same to undergo volumetric expansion. The volumetric expansion causes stress in the porous silicon 16, at least a portion of which, is transferred to the silicon exfoliation layer 34.

Still referring to step 290 in FIG. 4B, the oxidized substrate 12 is then flipped or turned over and brought into contact with a recipient substrate 40. The recipient substrate 40 may be formed from group IV semiconducting elements such as silicon or germanium. Alternatively, the recipient substrate 40 may be formed from group Ill-V compounds such as, for example, indium phosphide (InP), gallium phosphide (GaP), indium antimonide (InSb), indium arsenide (InAs), gallium antimonide (GaSb), gallium nitride (GaN), and silicon carbide (SiC). In yet another alternative, the recipient substrate 40 may be formed from group II-VI compounds such as, for instance, zinc oxide (ZnO), zinc selenide (ZnSe), cadmium sulfide (CdS), and cadmium telluride (CdTe). In yet another alternative, the recipient substrate 40 may be formed from crystal materials having useful optical properties such as, for example, yttrium orthovanadate (YVO₄), titanium dioxide (TiO₂), calcium carbonate (CaCO₃), lithium niobate (LiNbO₃), and lithium tantalate (LiTaO₃). The recipient substrate 40 may also be formed from other crystalline structures such as sapphire or quartz.

As seen in step 290, the recipient substrate 40 may have formed thereon a thermally grown oxide layer 42, for example, if the recipient substrate 40 is formed from silicon. In cases where the recipient substrate 40 is not silicon, the oxide layer 42 may be formed using PECVD. The thermally grown oxide layer 42 assists in bonding the recipient substrate 40 to the oxidized substrate 12. For example, the thermally grown oxide layer 42 may be formed from silicon dioxide. The thermally grown oxide layer acts as an interface or intermediate layer.

In step 300, the oxidized substrate 12 and the recipient substrate 40 are bonded together. The transfer or bonding of the oxidized substrate 12 (with the silicon exfoliation layer 34) may be performed using a hydrophilic wafer bonding process of the type disclosed herein. Next, as shown in step 310, the bonded structure is subject to a wet etching process to remove the porous silicon 16. For example, an etching solution of potassium hydroxide (KOH) may be used to etch away the porous silicon 16. Next, as seen in step 320, the oxide layer 18 may then be removed using another etching solution. For instance, an etching solution of hydrogen fluoride (HF) may be used to remove the oxide layer 18. Removal of the oxide layer 18 then exposes the stressed silicon exfoliation layer 34 on the recipient substrate 40. Because of the volumetric expansion of the porous silicon 16, a tensile stress is imparted to the silicon exfoliation layer 34 (also referred to as stressed thin film layer 34). The stressed thin film layer 34 is substantially, if not entirely, free of any dislocation defects. In addition, the stressed thin film layer 34 is homogeneously stressed across substantially the entire surface.

In one alternative aspect of the invention, the process disclosed in FIGS. 4A and 4B may be used to create a stressed thin film layer 34 under compressive stress. In this alternative embodiment, a layer of silicon nitride is deposited using LPCVD or PECVD on the recipient substrate 40 in place of oxide layer 42. The silicon nitride also enters the interstitial pores of the porous silicon 16. The deposition of silicon nitride within the porous silicon 16 causes contraction or shrinkage of the porous silicon 16. This, in turn, imparts a compressive stress on the stressed thin film layer 34. In contrast with the oxidation-based process disclosed above, there is no need for a subsequent annealing or heating step to contract or shrink the porous silicon 16. Contraction is caused by the deposition of silicon nitride on and in the porous silicon 16.

In this alternative embodiment, after the bonding step (step 300), the porous silicon 16 is etched away using an etching solution. For example, the porous silicon 16 may be etched away by a solution of potassium hydroxide (KOH) and phosphoric acid (H₂PO₄). The potassium hydroxide is used to etch away the porous silicon 16 while the phosphoric acid removes silicon nitride formed on the surface thereof. Of course, other etchants may also be used to remove the porous silicon 16 and adherent silicon nitride layer.

In another alternative embodiment, in the process illustrated in FIG. 1A, the silicon epilayer 14 is replaced with an epilayer of silicon germanium (SiGe). When a layer of silicon germanium is deposited or grown on p+ silicon substrate it naturally forms in a stressed, compressed state. This is due to the fact that silicon germanium has a higher lattice constant than silicon. However, after anodization and oxidation (step 120 in FIG. 1A), the compressed silicon germanium layer is relaxed. Consequently, volumetric expansion of the porous silicon 16 reduces or eliminates entirely the strain in the silicon germanium layer, which may facilitate the subsequent wafer bonding step due to the elimination of wafer curvature. The relaxed silicon germanium layer 14 may then be transferred to a secondary substrate as described herein.

The fabrication methods described herein are able to produce relatively large, homogenously strained semiconductor thin films that are substantially, if not entirely, free of dislocations. The methods described herein can be used to grow relatively thin semiconductor epitaxial layers that are below the critical thickness where dislocations are generated. Moreover, the methods do not employ graded buffer layers (like SiGe) that provide a source of dislocation generation. In addition, the use of a porous substrate like porous silicon that has a substantially uniform pore distribution ensures that subsequent processing that expands or contracts the porous substrate imparts a substantially uniform stress to the thin film. The thin film formed is this homogeneous with respect to stress across substantially the entire surface. Another benefit of the current method is that relatively low processing temperatures (e.g., around or below 500° C.) prevent or mitigate contamination of the stressed thin film from dopants.

Importantly, the methods described herein may be used to expand the total available spectrum of lattice constants available for manufacturing semiconductor devices. Rather than relying on a few discrete lattice constant points in the available spectrum, individual materials may be selectively stressed to modify their lattice constants. Tensile and/or compressive stresses applied to thin films alter the film's underlying lattice constant. In this regard, selectively applied stresses to thin films may be used to significantly expand the available lattice constants of semiconductor thin films. The varying lattice constants may be used to manufacture microelectronic or optoelectronic devices with new, useful properties.

While embodiments of the present invention have been shown and described, various modifications may be made without departing from the scope of the present invention. The invention, therefore, should not be limited, except to the following claims, and their equivalents.

What is claimed is:

1. A method of forming a stressed thin film on a substrate comprising:
growing a thin film of silicon on a first substrate;
transforming the first substrate to a porous substrate;
transforming the porous substrate containing the thin film of silicon to a stressed state such that at least a portion of the stress is transferred to the thin film of silicon on the porous substrate;
bonding the porous substrate containing stressed thin film of silicon to a second substrate; and
removing the porous substrate so as to deposit the stressed thin film of silicon to the second substrate.

2. The method of claim 1, wherein the stressed state of the porous silicon is one of an expanded state or a contracted state.

3. The method of claim 1, wherein the first substrate is transformed into a porous substrate by anodization.

4. The method of claim 1, wherein the first substrate comprises doped, p-type silicon.

5. The method of claim 1, wherein the transformation of the porous substrate containing the thin film of silicon to a stressed state is performed in the presence of oxygen.

6. The method of claim 1, wherein the transformation of the porous substrate containing the thin film of silicon to a stressed state is performed in the absence of oxygen.

7. The method of claim 1, wherein the stressed thin film is under tensile stress.

8. The method of claim 1, wherein the stressed thin film is under compressive stress.

9. The method of claim 1, wherein the step of removing the porous substrate is performed by etching.

10. The method of claim 1, wherein the step of removing the porous substrate is performed by chemical mechanical polishing.

11. A method of forming a stressed semiconductor thin film on a substrate comprising:
providing a porous substrate that includes an oxide layer disposed thereon;
bonding the porous substrate to a transfer substrate formed from a semiconducting material;
removing a portion of the transfer substrate so as to leave a semiconductor thin film on the porous substrate;
transforming the porous substrate containing the semiconductor thin film to a stressed state such that at least a portion of the stress is transferred to the semiconductor thin film on the porous substrate;
bonding the porous substrate containing the stressed semiconductor thin film to a recipient substrate; and
removing the porous substrate and oxide layer to expose the stressed semiconductor thin film on the recipient substrate.

12. The method of claim 11, wherein porous layer having the oxide layer is formed by:
growing a thin film of silicon on a substrate;
transforming the substrate to a porous substrate;
removing the thin film of silicon from the porous substrate;
subjecting the porous substrate to oxide or nitride deposition; and
planarizing the oxide or nitride surface on the porous substrate to form a substantially flat surface.

13. The method of claim 11, wherein the transfer substrate is subject to hydrogen ion implantation prior to bonding to the porous substrate, the portion of the transfer substrate being removed by exfoliation.

14. The method of claim 11, wherein the stressed semiconductor thin film is under tensile stress.

15. The method of claim 11, wherein the stressed semiconductor thin film is under compressive stress.

16. The method of claim 11, wherein the recipient substrate comprises a silicon substrate.

17. The method of claim 11, wherein the stressed semiconductor thin film is selected from the group consisting of a group IV element, a group II-VI compound, a group III-V compound, yttrium orthovanadate, titanium dioxide, calcium carbonate, lithium niobate, lithium tantalite, sapphire, and quartz.

18. The method of claim 11, wherein the transformation of the porous substrate containing the semiconductor thin film is performed in the presence of oxygen.

19. The method of claim 11, wherein the transformation of the porous substrate containing the semiconductor thin film is performed in the absence of oxygen.

20. An article of manufacture comprising:
a substrate;
an intermediate layer disposed on the substrate; and
a stressed thin film overlaying the intermediate layer, the stressed thin film being formed of a semiconductor material, the stressed thin film being homogenously stressed across substantially the entire surface of the substrate.
